(19) United States
(12) Patent Application Publication
(10) Pub. No.: US 2026/0181781 A1
(43) Pub. Date: Jun. 25, 2026

(54) PANEL LEVEL PACKAGING FOR MODULAR EMBEDDED DEVICES

(71) Applicant: SEMICONDUCTOR COMPONENTS INDUSTRIES, LLC, Scottsdale, AZ (US)

(72) Inventor: Ankit Bhushan SHARMA, Erding (DE)

(73) Assignee: SEMICONDUCTOR COMPONENTS INDUSTRIES, LLC, Scottsdale, AZ (US)

(21) Appl. No.: 18/989,676

(22) Filed: Dec. 20, 2024

(51) Int. Cl. H05K 1/14; H01L 23/00; H01L 23/31; H01L 23/495; H01L 25/065; H05K 1/03; H05K 1/18

(52) U.S. Cl. CPC H05K 1/145; H05K 1/0306; H05K 1/181; H10W 70/424; H10W 74/114; H05K 2201/10189; H10W 42/121; H10W 72/07323; H10W 72/07331; H10W 74/10; H10W 90/00; H10W 90/734

(57) ABSTRACT

A semiconductor device package includes a first panel including at least one first connection and a second panel including at least one second connection. The package includes a semiconductor device with a first surface of the semiconductor device attached to the first panel and connected to the at least one first connection, and with a second surface of the semiconductor device, opposed to the first surface of the semiconductor device, attached to the second panel and connected to the at least one second connection. The package includes a panel connector, with a first surface of the panel connector attached to the first panel, and with a second surface of the panel connector, opposed to the first surface of the panel connector, attached to the second panel, the panel connector thereby coupling the first panel to the second panel.

### TECHNICAL FIELD

This description relates to semiconductor device packaging.

### BACKGROUND

Semiconductor device packaging generally involves encasing one or more semiconductor devices in a protective housing that provides for electrical connections, heat dissipation, mechanical support, and/or electrical isolation. Many different types of semiconductor device packaging exist, providing varying degrees of packaging parameters. Such packaging parameters may include, but are not limited to, performance (e.g., speed or power handling) parameters, cost parameters, and/or size parameters.

Semiconductor device packages, including embedded device packages, are often produced through a partnership between the manufacturers of the semiconductor devices and providers of substrates and other packaging elements, e.g., printed circuit boards (PCBs). For example, the semiconductor device manufacturers may generally design and fabricate semiconductor dies, including providing detailed specifications about the layout, electrical requirements, and thermal characteristics of the die(s). PCB providers, for example, may ensure that relevant PCB designs accommodate related semiconductor dies, including designing layers for routing, power delivery, and thermal management. For embedded device packages, in which semiconductor dies are embedded directly into PCB layers, the PCB provider may be responsible for ensuring that the embedding process does not damage the dies and that electrical connections are reliable.

### SUMMARY

According to one general aspect, a semiconductor device package includes a first panel including at least one first connection and a second panel including at least one second connection. The semiconductor device package includes a semiconductor device, with a first surface of the semiconductor device attached to the first panel and connected to the at least one first connection, and with a second surface of the semiconductor device, opposed to the first surface of the semiconductor device, attached to the second panel and connected to the at least one second connection. The semiconductor device package includes a panel connector, with a first surface of the panel connector attached to the first panel, and with a second surface of the panel connector, opposed to the first surface of the panel connector, attached to the second panel, the panel connector thereby coupling the first panel to the second panel.

According to another general aspect, a package for an embedded semiconductor device includes a first panel and a second panel. The package includes a semiconductor device, with a first surface of the semiconductor device attached to the first panel, and with a second surface of the semiconductor device, opposed to the first surface of the semiconductor device, attached to the second panel. The package includes a panel connector, with a first surface of the panel connector attached to the first panel, and with a second surface of the panel connector, opposed to the first surface of the panel connector, attached to the second panel, the panel connector thereby bonding the first panel to the second panel. The package includes an encapsulant disposed between the first panel and the second panel, and around the semiconductor device and the panel connector.

According to another general aspect, a method of forming a semiconductor device package includes forming a cutout layer with at least a first cutout and a second cutout, disposing a semiconductor device in the first cutout and a panel connector in the second cutout, disposing the cutout layer, the semiconductor device and the panel connector between a first panel and a second panel, and performing a coupling process to couple the semiconductor device and the panel connector to the first panel and the second panel, and to form an encapsulant around the semiconductor device and the panel connector between the first panel and the second panel.

The details of one or more implementations are set forth in the accompanying drawings and the description below. Other features will be apparent from the description and drawings, and from the claims.

### BRIEF DESCRIPTION OF THE DRAWINGS

FIG. 1 is a side view of a modular embedded semiconductor device package.

FIG. 2 is an exploded side view of the modular embedded semiconductor device package of FIG. 1.

FIG. 3 is an example process flow for constructing the modular embedded semiconductor device package of FIG. 1.

FIG. 4 illustrates first example operations for forming a modular embedded semiconductor device package.

FIG. 5 illustrates second example operations for forming a modular embedded semiconductor device package.

FIG. 6 is a side view of a first example modular embedded semiconductor device package constructed using the operations of FIGS. 4 and 5.

FIG. 7A is a side view of the example semiconductor die(s) illustrated in FIGS. 4-6.

FIG. 7B is a side view of an alternate example semiconductor die that may be used in the modular embedded semiconductor device package of FIG. 6.

FIG. 7C is a side view of another alternate example semiconductor die that may be used in the modular embedded semiconductor device package of FIG. 6.

FIG. 8 is an example alternate implementation of the modular embedded semiconductor device packages of FIGS. 1 and 6.

FIG. 9 is an example alternate implementation of the modular embedded semiconductor device packages of FIGS. 1 and 6.

FIG. 10 is an example alternate implementation of the modular embedded semiconductor device packages of FIGS. 1 and 6.

FIG. 11 is an example alternate implementation of the modular embedded semiconductor device packages of FIGS. 1 and 6.

FIG. 12 is a flowchart illustrating example operations for forming modular embedded semiconductor device packages of FIGS. 1-11.

### DETAILED DESCRIPTION

Described techniques and embodiments provide improved semiconductor device packaging, including facilitating assembly, increasing safety margins, and enhancing reliability. For example, using described techniques, semiconductor dies may be packaged using pre-prepared panels that can easily be joined and fastened to enclose the semiconductor die(s).

As referenced above, packaging providers and semiconductor die makers often have a symbiotic relationship, with each party relying on the other's expertise for the success of final products, such as embedded semiconductor device packages. For example, semiconductor die makers depend on package providers for effective integration and manufacturing capabilities, while package providers need detailed semiconductor specifications to design boards that meet performance, size, and cost requirements. This partnership has led to developments in fields such as, e.g., mobile devices, automotive electronics, IoT, high-performance computing, and other technology areas in which embedded technologies are becoming increasingly prevalent.

In some cases, however, the package providers, e.g., substrate providers or PCB providers, may not have the tools necessary to process received semiconductor dies in a reliable, efficient, cost-effective manner. For example, manufactured semiconductor dies are often very thin and prone to warpage or breakage.

Semiconductor manufacturers may possess best-available tools to handle such dies, although even such semiconductor manufacturers may experience some level of die damage. Package providers, however, may be unlikely to possess such die handling tools, and may be forced to use tools that are prone to cause damage to semiconductor dies during embedding processes.

Moreover, even if the package providers are successful in moving and placing semiconductor dies, other aspects of the packaging processes may damage the semiconductor dies. For example, package providers may perform a series of steps to package a received die. For example, package providers may embed/laminate a die, drill through the embedded/laminated die to form electrical connections, provide various types of metallization, perform various photolithography/etching processes, and otherwise process the semiconductor die through various serial stages. These serial stages often involve heat, pressure, mechanical stress, and/or other forces being applied to the semiconductor die, either directly or indirectly through intermediate packaging components. As a result, a given semiconductor die may undergo multiple processing steps, any of which may individually or cumulatively affect a performance or reliability of a resulting packaged device in a negative manner.

To deal with the above and other difficulties of existing, conventional packaging techniques, either the semiconductor manufacturer and/or the package provider may process each semiconductor die in order to make each such semiconductor die more robust and less prone to failure during subsequent packaging processes. For example, the semiconductor manufacturer may provide various types of metal and/or laminate to a die, to make the die more structurally sound and more resistant to damage during packaging processes. Such efforts may increase cost, size, and time required during packaging operations.

Described techniques, in contrast, enable modular packaging of a semiconductor die at a facility of, e.g., a semiconductor manufacturer, using pre-prepared panels received from a package provider. The pre-prepared panels may thus be joined around the semiconductor die in a convenient and reliable manner, while minimizing handling of the die and/or processing that may affect the die.

For example, a semiconductor manufacturer, or any facility with suitable die-handling equipment, may order such pre-prepared panels from a package provider, e.g., a PCB provider. The pre-prepared panels may be provided with all required electrical connections and stress relief elements (e.g., relief elements for heat stress and/or mechanical stress).

Then, in the example, the semiconductor manufacturer may simply place the die in a first one of the panels and join the second one of the panels to the first panel and around the die. Subsequent fastening, lamination, or encapsulation of the die within the joined panels may be the only such processing experienced by the die during the packaging process.

As a result of the above approach to packaging, die handling may be restricted to facilities with appropriate equipment and expertise available to avoid damaging the die during packaging. Package providers that do not possess such equipment or ability are spared from purchasing such equipment, as well as the potential of damaging an expensive and fragile semiconductor die. Moreover, handling and other processing of the die may be limited, and may be substantially reduced with respect to existing packaging techniques.

As a result, the die may be less likely to be damaged from cumulative effects of multiple processing operations. Therefore, a need to protect the die by adding structural support elements of metal or other material may be reduced or eliminated, so that a cost, size, and time to produce the die may be reduced, as well.

Further, semiconductor packaging may be performed in a modular, parallel manner, rather than in the conventional serial manner. For example, joining of multiple submodules may be performed in a single step or single set of operations, so that an overall time to completion of packaging operations may be reduced.

In some implementations, described semiconductor packages may be constructed by a single provider having both packaging and die handling capabilities. In these scenarios, described techniques provide at least the advantages described above related, e.g., to modular, parallel construction of semiconductor packages, as well as a reduction in number of operations involving mechanical or thermal stress that involve sensitive semiconductor dies.

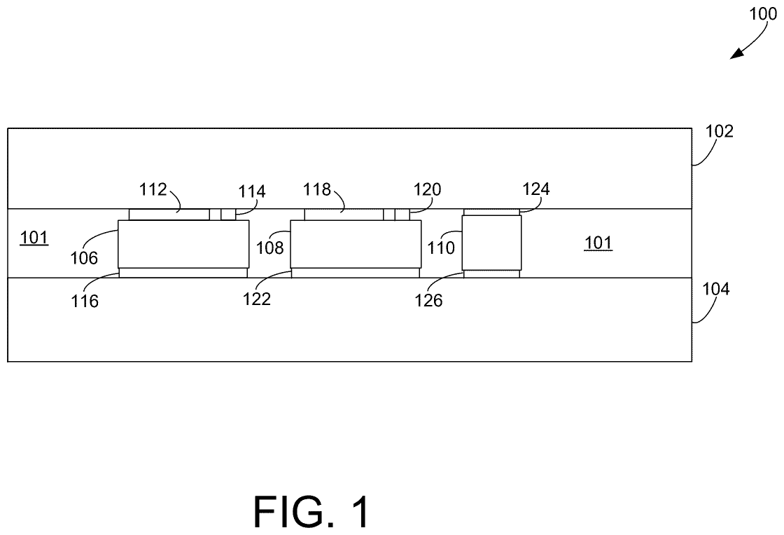

FIG. 1 is a side view of a modular embedded semiconductor device package 100. In the example of FIG. 1, the modular embedded semiconductor device package 100 includes a first panel 102, also referred to as an upper panel or a top panel, and a second panel 104, also referred to as a lower panel or a bottom panel.

An encapsulant 101 is disposed between the first panel 102 and the second panel 104. As shown, the encapsulant 101 at least partially secures a first semiconductor die 106 and a second semiconductor die 108 between the first panel 102 and the second panel 104.

The first panel 102 and the second panel 102 may represent any suitable packaging material, such as a PCB panel or other substrate panel. Although not illustrated for the sake of simplicity in the example of FIG. 1, the first panel 102 and/or the second panel 104 may include various additional packaging elements, such as, e.g., electrical connections. The encapsulant 101 may represent any suitable lamination or mold material, various examples of which are provided below, or would be apparent.

Further in FIG. 1, a panel connector 110 is illustrated as connecting the first panel 102 and the second panel 104 to one another. As shown, the first semiconductor die 106 and the second semiconductor die 108 may also be connected to the first panel 102 and to the second panel 104.

More specifically, the first semiconductor die 106 is illustrated as being connected to the first panel 102 by a sinter layer 112 and a sinter layer 114. The first semiconductor die 106 is also illustrated as being connected to the second panel 104 by a sinter layer 116. The second semiconductor die 108 is illustrated as being connected to the first panel 102 by a sinter layer 118 and a sinter layer 120. The second semiconductor die 108 is also illustrated as being connected to the second panel 104 by a sinter layer 122. Meanwhile, the panel connector 110 is illustrated as being connected to the first panel 102 by a sinter layer 124, and as being connected to the second panel 104 by a sinter layer 126.

For example, the first semiconductor die 106 and the second semiconductor die 108 may represent transistors, so that the sinter layers 112, 118 are positioned to provide source connections to respective sources of the first semiconductor die 106 and the second semiconductor die 108, while sinter layers 114, 120 are positioned to provide gate connections to respective gates of the first semiconductor die 106 and the second semiconductor die 108, and sinter layers 116, 122 are positioned to provide drain connections to respective drains of the first semiconductor die 106 and the second semiconductor die 108. Of course, these are merely examples, and the first semiconductor die 106 and the second semiconductor die 108 may represent any suitable type of semiconductor device, including, e.g., other types of transistors, diodes, and the like. Moreover, a given semiconductor die may include one or more semiconductor devices, and the package 100 may include one, two, or more semiconductor dies. In various such implementations, at least one sinter layer (or other connecting layer, e.g., solder) may be used between a first surface (e.g., a top surface) of each semiconductor die and the first panel 102, and between a second surface (e.g., a bottom surface) of each semiconductor die and the second panel 104.

Further, the panel connector 110 is attached to the first panel 102 by a sinter layer 124, and to the second panel 104 by a sinter layer 126. For example, the panel connector 110 may represent a metal connector, e.g., a copper connector, such as, e.g., a copper plug or copper coin. Although only the single panel connector 110 is illustrated, it will be appreciated that any suitable number and type of panel connector may be used. For example, when the panel connector 110 includes metal, the panel connector 110 may also serve to provide electrical and/or thermal conductivity to facilitate operations of the first semiconductor die 106 and/or the second semiconductor die 108. In other examples, the panel connector 110 may be provided using a non-conducting material.

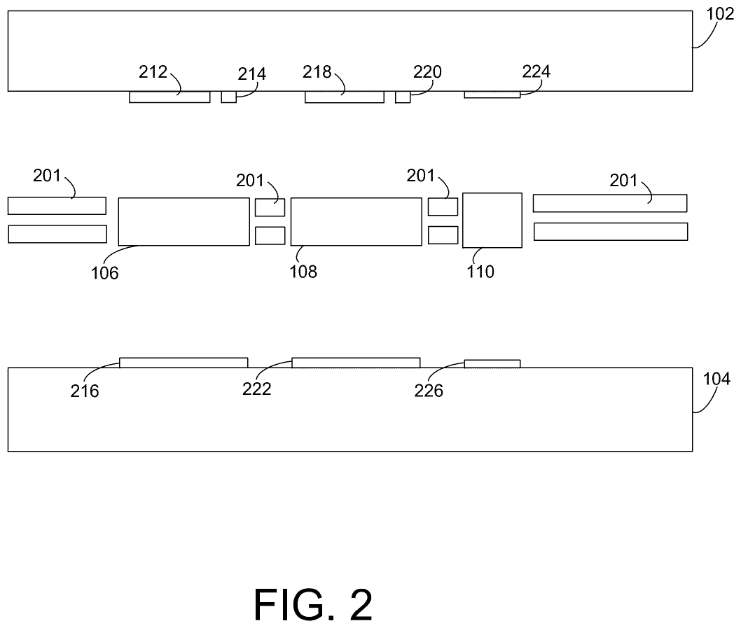

FIG. 2 is an exploded side view of the modular embedded semiconductor device package of FIG. 1. FIG. 2 also illustrates an assembly stage in which the first panel 102, the second panel 104, the first semiconductor die 106, the second semiconductor die 108, and the panel connector 110 have been prepared for package assembly.

More particularly, the first panel 102 has been prepared with layers 212, 214, 218, 220, 224 of sinter paste, e.g., Ag sinter paste, which correspond respectively to sinter layers 112, 114, 118, 120, 124 of FIG. 1. Similarly, the second panel 104 has been prepared with layers 216, 222, 226 of sinter paste, which correspond respectively to sinter layers 116, 122, 126 of FIG. 1.

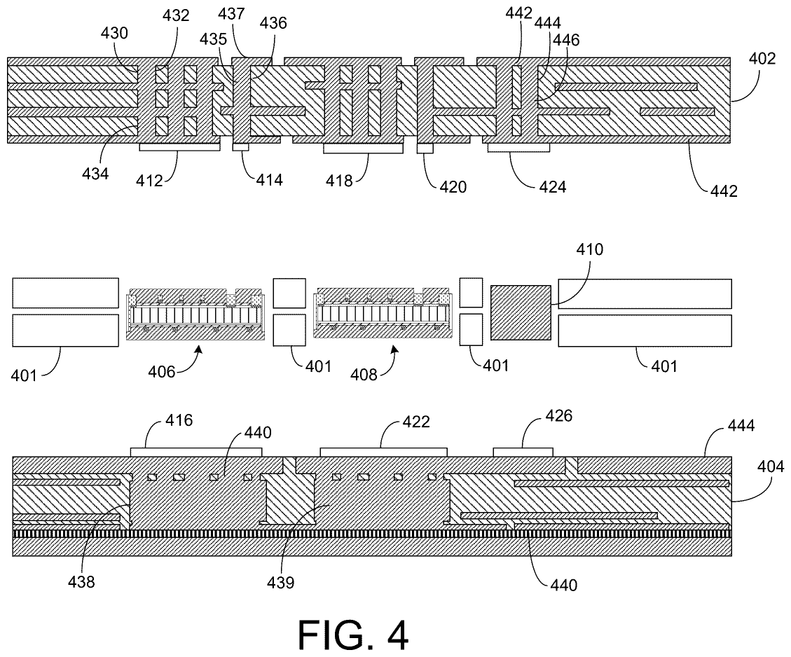

Further illustrated in FIG. 2 is a lamination layer(s) 201 of, e.g., pre-preg material. Pre-preg material generally refers to a reinforcing material, such as fiberglass or other fabrics, impregnated with a partially cured resin, such as epoxy, which provides thermal and mechanical stability. As described in detail, below (e.g., with respect to the process sequence of FIGS. 4-6), the lamination layer 201 may be subjected to heat and/or pressure to provide the encapsulant 101 of FIG. 1.

Thus, FIG. 2 illustrates that the panels 102, 104 may be built by a package provider, e.g., PCB provider, and provided to a manufacturer (and/or designer) of the semiconductor dies 106, 108. The semiconductor manufacturer may already possess the semiconductor dies 106, 108, the lamination layer 201, and perhaps the panel connector 110. Alternatively, the panel connector 110 may be provided by the packaging provider.

Upon receipt of the panels 102, 104, which may already contain all (or at least a portion of) necessary electrical and thermal interconnects, the semiconductor manufacturer may complete assembly of the package 100 of FIG. 1 merely by joining the panels 102, 104 to the semiconductor dies 106, 108 and to the panel connector 110, and then proceeding with one or more processing cycles for processing the sinter paste layers 212, 214, 216, 218, 220, 222, 224, and 226 and the lamination layer(s) 201, to thereby obtain corresponding sinter layers 112, 114, 116, 118, 120, 122, 124 and encapsulant 101 of FIG. 1.

As noted above, in conventional techniques, a semiconductor die(s) is subjected to a series of processing steps at a package provider, and may thus undergo multiple rounds of applied heat, pressure, and/or mechanical stress. In contrast, the processing cycle(s) described above are the only processing cycle(s) to which the semiconductor dies 106, 108 are required to undergo during assembly of the package 100 of FIG. 1.

Using described techniques, semiconductor manufacturers are provided with more choice with respect to selection of a package provider, because, e.g., package providers are not required to be able to provide reliable die handling capabilities. Instead, package providers may avoid handling dies altogether, and may simply ship panels designed according to specifications provided by a receiving semiconductor manufacturer.

Meanwhile, the semiconductor manufacturer(s) can leverage their die handling capabilities in assembling a complete package from desired die(s) and received panels. The semiconductor manufacturers can also leverage existing and limited processing techniques at their facilities, such as the temperature and pressure techniques referenced above for processing sinter paste and lamination layers. In particular, the semiconductor manufacturers are not required to provide wet chemistry techniques, such as may be used, e.g., for cleaning, etching, resist stripping, or deposition/plating.

FIG. 2 further illustrates that the panel connector 110 may be used during assembly to position and/or orient the panels 102, 104 with respect to one another and with respect to the semiconductor dies 106, 108. Although FIGS. 1 and 2 illustrate the single panel connector 110, two or more panel connectors may be used. Similarly, although FIGS. 1 and 2 illustrate the two semiconductor dies 106, 108, a single die may be used, or three or more dies may be used.

The panel connector 110 may also be provided in any desired or suitable size, so as to ensure a reliable connection between the panels 102, 104. For example, increasing a surface area of a top and bottom surface(s) of the panel connector 110 enables corresponding increases in the quantities of sinter paste 224, 226, which may therefore provide a more stable bond with corresponding panels 102, 104, and a more reliable packaging overall. As a result, the panel connector 110, along with the lamination layer(s) 201 (encapsulant 101), maintain a strong connection between the panels 102, 104 while minimizing mechanical stress on the dies 106, 108 (and on electrical connections thereto).

The panel connector 110, as referenced above, may be made of metal, e.g., copper, and may be referred to as a metal preform, metal coin, metal token, or metal plug. In addition to facilitating assembly of the package 100 as just referenced, the panel connector 110, when made of metal, may be used to provide desired electrical and/or thermal connections. For example, in the following examples of FIGS. 4-6, the first panel 102 is primarily used for electrical connections to the dies 106, 108, while the second panel 104 is used for both electrical connections and thermal relief. Therefore, the panel connector 110 may provide electrical connection(s) between the second panel 104 and the first panel 102, as well as assisting in heat routing/dissipation.

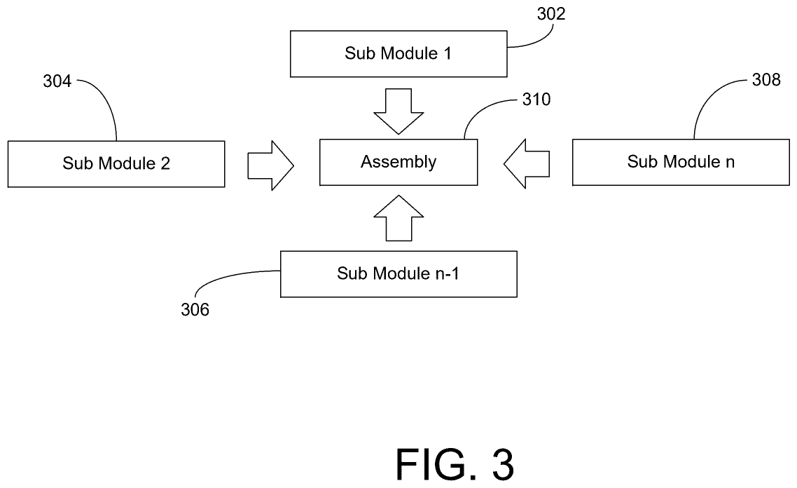

FIG. 3 is an example process flow for constructing the modular embedded semiconductor device package of FIG. 1. FIG. 3 illustrates that multiple submodules 302, 304, 306, 308 may be assembled into a single assembly 310. For example, a submodule may represent a panel such as the panel 102 or the panel 104. A submodule may represent one or more semiconductor dies, such as the dies 106, 108.

Thus, FIG. 3, consistent with the examples of FIGS. 1 and 2, illustrates that a single assembly operation 310, including one or more processing steps of applying heat and/or pressure, may be used to join two or more submodules, represented in FIG. 3 as submodules 302, 304, 306, 308.

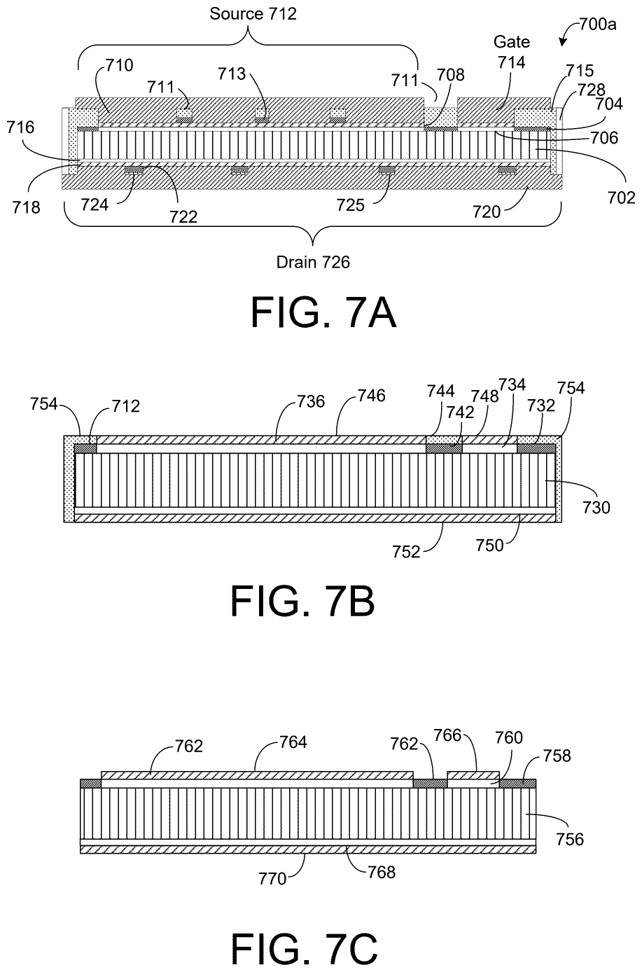

FIG. 4 illustrates first example operations for forming a modular embedded semiconductor device package. Similar to FIG. 2, FIG. 4 illustrates an assembly stage in which an first (upper) panel 402 and a second (lower) panel 404 are used together with one or more lamination layer(s) 401 to embed and otherwise assemble semiconductor dies 406, 408, using a panel connector 410. Further description of the device package of FIG. 4 is primarily provided with respect to connections to, and packaging of, the semiconductor die 406, but it will be understood that similar descriptions apply to the semiconductor die 408 and its corresponding connections and packaging, as well. Additionally, a more detailed description of the individual semiconductor dies 406, 408 is provided below, with respect to FIG. 7A.

As shown in FIG. 4, sinter paste 412 and 414 correspond respectively to source and gate connections of the semiconductor die 406, while sinter paste 416 corresponds to a drain connection of the semiconductor die 406. Similarly, sinter paste 418 and 420 correspond respectively to source and gate connections of the semiconductor die 408, while sinter paste 422 corresponds to a drain connection of the semiconductor die 408.

Sinter paste 424 and sinter paste 426 similarly serve to bond the panel connector 410 to the first panel 402 and the second panel 404, respectively. As described, the panel connector 410 thus serves to align the semiconductor dies 406, 408 for assembly, provide a strong connection between the panels 402, 404, and provide electrical/thermal connectivity between metal elements of the panels 402, 404.

A source region of the semiconductor die 406 is attached by a portion of the sinter layer 412 to a plurality of source contacts 434 established using source vias 430, thereby defining a source connection 432. Similarly, a gate region of the semiconductor die 406 is attached by a portion of the sinter layer 414 to a plurality of gate contacts 435 established using gate vias 436, thereby defining a gate connection 437.

At an opposed side of the semiconductor device 406, the semiconductor device 406 is attached by a sinter layer 416 to drain contact(s) 438. In the example of FIG. 4, the semiconductor device 406 and the semiconductor device 408 are connected using metal connectors 438, 439, respectively, through drain vias 440. Other techniques for establishing a drain connection(s) may be used, as well.

Further in FIG. 4, the semiconductor dies 406, 408 are disposed and enclosed in cutouts of a lamination layer 401. The lamination layer 401 provides a core layer that may include, e.g., any suitable material or composite material used for semiconductor packaging. For example, the lamination layer 401 may be formed from FR-4 (Flame Retardant 4), a composite material of woven fiberglass or other reinforcing material, impregnated with an epoxy resin. The lamination layer 401 may be prepared with cutouts in which to place the semiconductor dies 406, 408, and the panel connector 410 may provide a mechanical as well as electrical connection to stabilize the overall semiconductor package of FIG. 4.

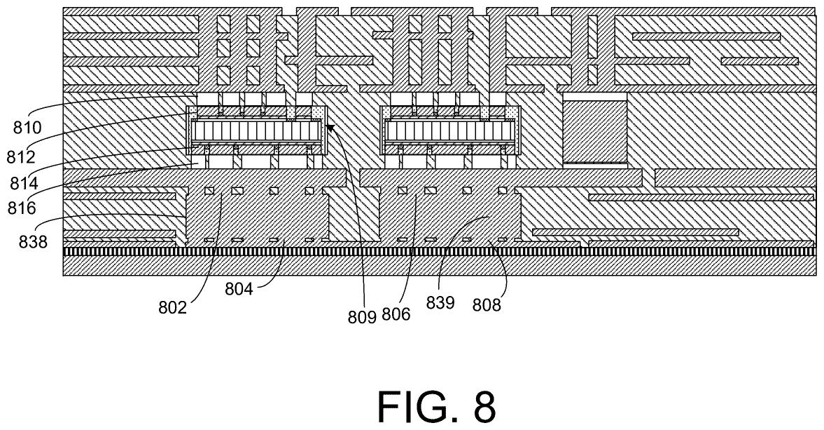

In the second panel 404, a thick metal inlay 438 is provided as a drain connection for the first semiconductor die 406. In the example, a second thick metal inlay 439 similarly provides a drain connection to the semiconductor die 408, and both metal inlays 438, 439 are electrically connected to the sinter paste 426, as shown. As shown, the thick metal inlay 438 includes microvias 437 through which connections to the sinter paste 416 may be made. Additional and alternative implementations of the metal inlays 438, 439 are provided below, e.g., with respect to FIGS. 8-11.

Further in FIG. 4, a thermal pre-preg layer 440 is positioned across a bottom of the metal inlays 438, 439, and across an entirety of the second panel 404. In the first panel 402, a panel connector connection 442 is established using vias 444 with metal contacts 446 provided therein, and thereby to the sinter paste 424. Thus, in FIG. 4, the first panel 402 is primarily used to provide electrical connections and optimizations (e.g, current routing), while the second panel 404 provides thermal management in addition to electrical connectivity (e.g., to drain connections of the semiconductor dies 406, 408).

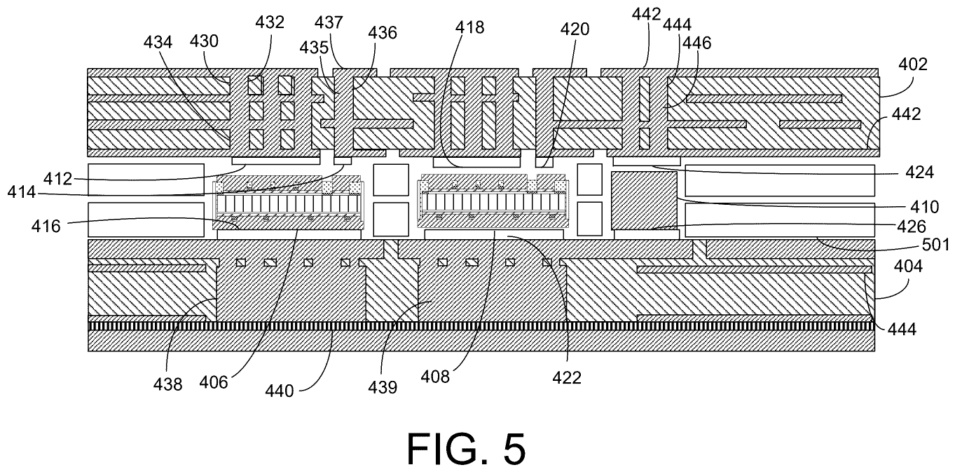

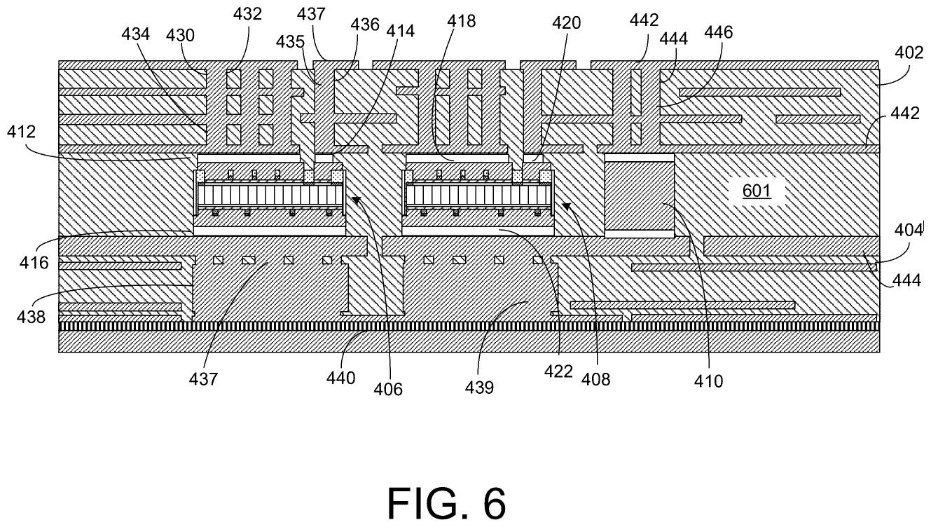

Metal layer 442 in the first panel 402, and metal layer 444 in the second panel 404, provide stable support and contact for the lamination layer 401, as shown further in FIGS. 5 and 6. In addition, the metal layers 442, 444 provide a suitable surface(s) for the various layers of sinter paste 412, 414, 416, 418, 420, 422, 424, 426.

FIG. 5 illustrates second example operations for forming a modular embedded semiconductor device package. In FIG. 5, the semiconductor dies 406, 408 and the panel connector 410 are placed within cutouts of the lamination layer 401, and onto respective layers of sinter paste 416, 422, and 426 of the second panel 404. First panel 402 is placed onto the lamination layer 401, the semiconductor dies 406, 408, and the panel connector 410. Layers of sinter paste 412, 414 are positioned on source and gate connections of the semiconductor die 406, and layers of sinter paste 418, 420 are positioned on source and gate connections of the semiconductor die 408. Layer of sinter paste 424 is positioned on the panel connector 410.

FIG. 6 is a side view of a first example modular embedded semiconductor device package constructed using the operations of FIGS. 4 and 5. In FIG. 6, heat and pressure are applied to the structure of FIG. 5, causing the lamination layer 401 of FIG. 5 to form an encapsulant 601 in FIG. 6. Further, all of the various layers of sinter paste 412, 414, 416, 418, 420, 422, 424, 426 form sinter bonds with corresponding portions of the semiconductor dies 406, 408 and the panel connector 410.

In the preceding examples of FIGS. 4-6, the semiconductor dies 406, 408 provide more detailed examples of the semiconductor dies 106, 108, which it may be appreciated that the semiconductor dies 106, 108 represent virtually any semiconductor die that may be included in the panel level packaging for modular embedded devices of FIGS. 1-3. FIGS. 7A-7C represent, by way of example and not limitation, more additional details regarding examples of semiconductor dies that may be used.

FIG. 7A is a side view of the example semiconductor die(s) 406, 408 illustrated in FIGS. 4-6, shown as semiconductor die 700a. As illustrated and described, the semiconductor die 700a illustrates an example in which patterned metal layer(s) may be provided on the tops and/or bottoms of semiconductor dies, which prevent warpage of the dies while permitting use of metal layers with desired levels of thickness. With such thicker metal layers, a danger of drilling overshoot is reduced when forming connection vias, and faster/more inexpensive drilling techniques may be used to form the vias.

For example, double-sided patterned metal layers may be formed on both a top and bottom of a semiconductor die. Such double-sided patterned metal layers compensate mechanical stress caused by one another, so that a net mechanical stress imposed on the die is reduced, and a likelihood of warpage is correspondingly reduced.

For example, a patterning of a top-side metal layer may be dictated or influenced by a pattern(s) of metal contacts formed on the top side of the semiconductor die (e.g., a source contact and a gate contact). In some implementations, a bottom-side metal layer may then be provided over an entirety or almost an entirety of the bottom side of the semiconductor die.

In other implementations, the bottom-side metal layer may be patterned. For example, such a patterning of a bottom-side metal layer may be selected to reduce or compensate for mechanical stress and warpage that would otherwise be caused by the top-side metal layer.

In some examples, a simulation tool may be used to determine the top-side and/or bottom-side metal patterning. For example, the top-side patterning may be dictated at least partially by a layout of top-side contact pads of the semiconductor die, and may be input to the simulation tool with a request for corresponding bottom-side patterning that minimizes warping of the die. In other examples, both the top-side and the bottom-side patterning may be output based on various factors, including, e.g., the top-side contacts, a thickness or other parameter of the die, a thickness of the patterned metal layers, and/or a degree of permissible warpage. Put another way, warpage may be used as a simulation parameter to be minimized when simulating potential top-side and/or bottom-side patterning.

In some implementations, the patterned metals may be provided using various masking and plating techniques. For example, masks may be provided on the top side and/or bottom side of a semiconductor die to define a desired pattern(s). Then, copper plating may be provided simultaneously, in a single process, on both a top side and bottom side of the semiconductor die.

In some implementations, molding may be provided within any grooves or other spaces defined by the metal patterns, e.g., for further stability and/or for electrical isolation. Grinding may then be performed to reduce a thickness of the patterned metal and the molding, so as to achieve a desired thickness of the metal plating. Such grinding may also serve to ensure a uniform and consistent height of the metal and molding across a surface(s) of the semiconductor die.

In some implementations, embedded sidewalls may be provided at one or more sides of the semiconductor die. Such sidewalls may provide enhanced stability, and may cause the semiconductor die to be less likely to experience damage when being embedded, e.g., into a PCB or other substrate.

Moreover, some embedded packaging techniques are prone to difficulties resulting from conductive anodic filaments (CAFs), which refer to, e.g., migration of copper or other metal ions through non-conductive materials under the influence of an electric field. For example, prepreg materials used in embedded packaging techniques are prone to CAF growth. Such CAF growth may result in, e.g., short circuits or other failure mechanisms. The addition of epoxy mold compound (EMC) sidewalls provides protection against CAF growth and thereby results in increased reliability and stability of embedded packages.

In some implementations, fanout layers may be provided in conjunction with the patterned metal layers. Such fanout layers may serve, e.g., to facilitate or enhance external connections to the semiconductor die.

Using described techniques, a metal thickness on a top side of a semiconductor die may be increased to be in the range of, e.g., 10 microns-200 microns, or more. As a result of using described techniques, warpage or other damage to semiconductor devices may be reduced, and vias for the semiconductor devices may be formed quickly, inexpensively, and reliably. Thus, semiconductor manufacturers may experience a higher yield of embedded packages received from package providers, and package providers may experience a more streamlined and efficient process(es) for providing the embedded packages.

In FIG. 7A, the semiconductor die 700a includes such double-sided plating, with fanout layers. Specifically, in the example of FIG. 7A, a semiconductor die 702 is illustrated as having a first or top side in an upper portion of the figure, and a second or bottom side on a lower portion of the figure. On the top side of the semiconductor die 702, a sinter layer 706 is used to attach metallization layer 708 to the semiconductor die 702. A passivation layer 704 is disposed between portions of the sinter layer 706 and the metallization layer 708.

A top-side patterned metal 710, also referred to as a first-side patterned metal, is provided using a patterned top-side metal plating layer, as referenced above. The pattern formed in, or using, the top-side patterned metal 710 may be referred to as a stress-relief pattern. In the example of FIG. 7A, a first portion of the top-side patterned metal 710 is disposed on a portion of the metallization layer 708 connected to a source portion of the semiconductor die 702. The source portion of the semiconductor die 702, a source portion of the metallization layer 708, and corresponding portion of the top-side patterned metal 710 are collectively referred to as a source 712. A second portion of the top-side patterned metal 710 is disposed on a portion of the metallization layer 708 connected to a gate portion of the semiconductor die 702, all of which are collectively referred to as a gate 714.

A passivation layer 713, e.g., polyimide passivation layer, is disposed in spaces or openings 711 of the top-side patterned metal 710. The passivation layer 713 may have been used as part of a mask used to form the top-side patterned metal 710, along with the passivation layer 704.

Further in FIG. 7A, an encapsulant 715 is illustrated as surrounding and enclosing portions of the top-side patterned metal 710 and the semiconductor die 702. As shown, the encapsulant 715 is also disposed within the openings 711 of the top-side patterned metal 710. The encapsulant 715 may represent any suitable mold material, e.g., resin or epoxy.

Similar comments as provided above with respect to the top or first side of the semiconductor die 702 apply to an opposed side of the semiconductor die 702, referred to as a second or bottom side of the semiconductor die 702. Specifically, on the bottom side of the semiconductor die 702, a sinter layer 716 is used to attach metallization layer 718 to the semiconductor die 702.

A bottom-side patterned metal 720, also referred to as a second-side patterned metal, provides a patterned bottom-side metal plating layer, as referenced above. Also as above, the pattern formed in, or using, the bottom-side patterned metal 720 may be referred to as a stress-relief pattern. In the example of FIG. 7A, the bottom-side patterned metal 720 is disposed on the metallization layer 718 that is itself connected to a drain portion of the semiconductor die 702, all of which are collectively referred to as a drain 726.

A passivation layer 722 is disposed in spaces or openings 725 of the bottom-side patterned metal 720. The passivation layer 722 may have been used as part of a mask used to form the bottom-side patterned metal 720. As further illustrated, encapsulant 724 is disposed within the openings 725.

FIG. 7A thus illustrates that the term patterned metal refers to a metal layer, e.g., a plated metal layer, having openings or spacings formed therein so that the metal layer exhibits a pattern defined by the openings. That is, the top-side patterned metal 710 exhibits a pattern defined by the openings 711, including spacing between the source 712 and the gate 714, while the bottom-side patterned metal 720 exhibits a pattern defined by the openings 725.

The patterned metals 710, 720 thus provide for relief of mechanical stress on the semiconductor die 702, making the semiconductor die 702 less likely to warp or break. For example, a total quantity or mass of the top-side patterned metal 710 and the bottom-side patterned metal 720 may be the same or almost the same, thereby providing an equilibrium with respect to forces applied to the semiconductor device 700a during handling thereof. In particular, as referenced above, the top-side patterned metal 710 (and the encapsulant 715) and the bottom-side patterned metal 720 (and the encapsulant 724) may both be exposed to a grinding process that reduces a height of both of the top-side patterned metal 710 and the bottom-side patterned metal 720 to a desired height. Such grinding process(es) may further ensure a uniform height across an entirety of the topside patterned metal 710 and of the bottom-side patterned metal 720.

Because of the equilibrium of opposed forces applied by the top-side patterned metal 710 and the bottom-side patterned metal 720 during wafer handling, a thickness of the patterned metals 710, 720 may be increased relative to existing metal layers formed on a semiconductor die, without causing increased incidents of breakage or warpage. For example, a thickness of the metal layers 710, 720 may be 10 microns, 50 microns, 100 microns, or more. As a result, and as illustrated in more detail, below, drilling of vias through the patterned metal layers 710, 720 to form electrical connections may be performed quickly and inexpensively, without concern for overdrilling that may cause damage to the semiconductor die 702.

In the example of FIG. 7A, the semiconductor device 700a represents a transistor, which may be any suitable transistor made from any suitable material, such as a Silicon (Si), Si Carbide (SiC), or Gallium Nitride (GaN) transistor. Of course, these are just examples, and various types of semiconductor devices, e.g., diodes, may be included, or combinations of devices (e.g., transistors, diodes) may be included.

For example, the semiconductor device 100 may represent various types of power transistors, such as insulated-gate bipolar transistors (IGBTs), power metal-oxide-semiconductor field effect transistors (MOSFETs), and so forth. Electrical interconnections within a high-power semiconductor device package can include, for example, bond wires, conductive spacers, metal and insulating built up layers, and conductive clips.

Although sinter, e.g., Ag sinter, is mentioned above, other die attach materials or techniques may be used, e.g., solder. Any suitable metal may be used for metallization layers, e.g., alloys of Titanium, nickel, and/or silver. Copper plating provides on example of material and techniques that may be used to form the top-side and bottom-side patterned metals 710, 720, but other suitable materials and techniques may be used, as well.

FIG. 7A further includes sidewalls 728. For example, sidewalls 728 may be formed using EMC core sidewalls. The sidewalls 728 provide additional stability and reliability during handling, while also providing protection against CAFs that may lead to short circuits or other device failures.

In the example of FIG. 7A, the metal layers 710, 714, 720 are illustrated as including fanout layers to provide easy and reliable source/gate/drain connections. In alternate implementations, the fanout layers need not be provided. For example, the metal layers 710, 714, 720 may have outer surfaces that have the same height(s) as corresponding openings 711, 725.

In the example of FIG. 7A, a semiconductor die 730 is illustrated as having a first or top side in an upper portion of the figure, and a second or bottom side on a lower portion of the figure. On the top side of the semiconductor die 730, a sinter layer 734 is used to attach metallization layer 736 to the semiconductor die 730. A passivation layer 732 is disposed between portions of the sinter layer 734 and the metallization layer 736. In more detail, a portion 742 of the passivation layer 732 and an encapsulant 744 separates a source portion 746 of the sinter layer 734 and the metallization layer 736 and a gate portion 748 of the sinter layer 734 and the metallization layer 736.

On the bottom side of the semiconductor die 730, a sinter layer 750 is used to attach metallization layer 753 to the semiconductor die 730. The bottom side of the semiconductor die 730 defines a drain portion. In FIG. 7B, both the bottom side metallization layer 752 and the top side metallization layer 736 provide sinterable/solderable surfaces for attaching further metal/electrical connections.

FIG. 7B further include sidewalls 754. In the example of FIG. 7B, the sidewalls 754 provide a similar type of protection as the encapsulant 715 and sidewalls 728 of FIG. 7A, but without a separate portion formed using EMC core or similar material.

Thus, FIG. 7A generally provides a chip scale package providing a sturdier structure that is less susceptible to die handling and die processing errors than the chip scale package of FIG. 7B, but that is more difficult and time consuming to produce than the structure of FIG. 7B. In described techniques, panel-based assembly processes that enable die handling exclusively by a semiconductor manufacturer, rather than by a packaging provider, may be suitably executed using the structure of FIG. 7B, thereby saving time and expense with respect to a final package.

In the example of FIG. 7C, a semiconductor die 756 is illustrated with a top side having a sinter layer 760 and a metallization layer 762, along with a passivation layer 758. A portion 762 of the passivation layer 758 separates a source portion 764 and a gate portion 766. On the bottom side of the semiconductor die 756, a sinter layer 768 attaches a metallization layer 770 to define a drain portion. As in FIG. 7B, in FIG. 7C, both the bottom side metallization layer 770 and the top side metallization layer 762 provide sinterable/solderable surfaces for attaching further metal/electrical connections.

FIG. 7C thus illustrates an example that is faster and less expensive to produce than the examples of FIGS. 7A, 7B, and that is practical to use in the modular, panel-level assembly processes described herein because, e.g., the device of FIG. 7C may be handled exclusively by the semiconductor manufacturer or other entity equipped with best-available die handling equipment, and because of suitable protection from mechanical and thermal stresses by the panel structures of FIGS. 1-6.

FIG. 8 is an example alternate implementation of the modular embedded semiconductor device packages of FIGS. 1 and 6. In FIG. 8, inlays 838, 839 provide example alternative implementations of inlays 438, 439 of FIGS. 4-6. Specifically, as shown, the inlay 838 includes microvias 802, 804 at upper and lower portions, respectively of the inlay 838. Similarly, the inlay 839 includes microvias 806, 808. In contrast, for example, the inlay 438 of FIGS. 4-6 includes only microvias 437. The structure of FIG. 8 provides organic isolation and good thermal conductivity.

Further in FIG. 8, semiconductor device 809 is illustrated with an alternate chip scale packaging, as compared to the examples of FIGS. 4-6 or FIGS. 7A-7C. Specifically, as shown, an upper portion of the semiconductor device 809 includes source and gate connections established through thick metal layer 812 attached using corresponding sinter portions 810. As shown, and in comparison, e.g., to the examples of FIGS. 6 and 7A, no fanout layer is included for the semiconductor device 809. Similarly, a bottom portion of the semiconductor device 809 includes drain connection(s) established through thick metal layer 814 attached using corresponding sinter portions 816, without including a fanout layer.

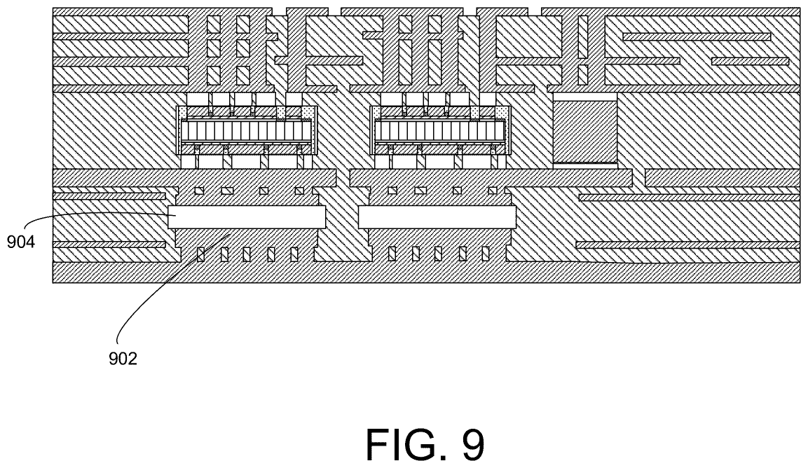

FIG. 9 is an example alternate implementation of the modular embedded semiconductor device packages of FIGS. 1 and 6. FIG. 9 is similar to FIG. 8, but includes a metal inlay 902 with a ceramic isolation layer 904 encapsulated therein. Further, in the example, the thermal pre-preg layer 440 of FIGS. 4-6 is omitted

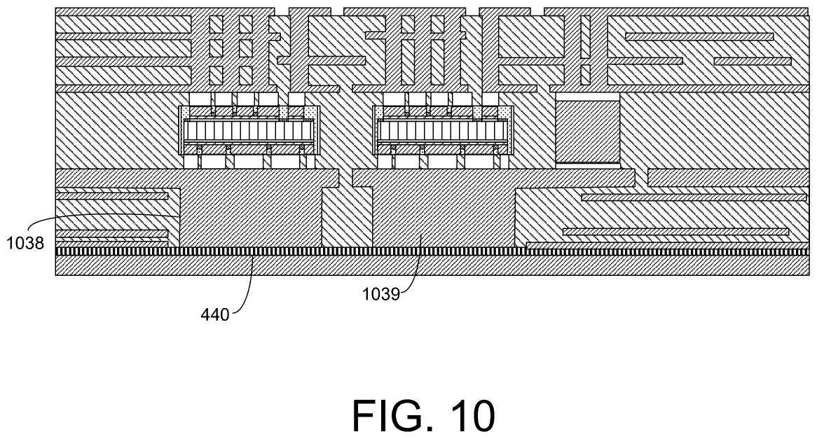

FIG. 10 is an example alternate implementation of the modular embedded semiconductor device packages of FIGS. 1 and 6. In the example of FIG. 10, inlays 1038, 1039 may be implemented, e.g., as copper leadframes with no microvias and positioned directly on thermal pre-preg layer 440.

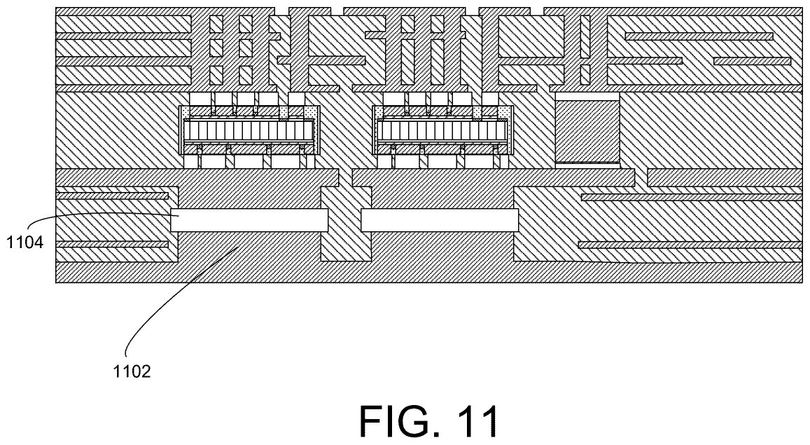

FIG. 11 is an example alternate implementation of the modular embedded semiconductor device packages of FIGS. 1 and 6. FIG. 11 combines features of the examples of FIGS. 9 and 10, and includes, e.g., a full plating (no microvias) inlay 1102 (similar to the example of FIG. 10) that includes a ceramic isolation layer 1104 (similar to the example of FIG. 9).

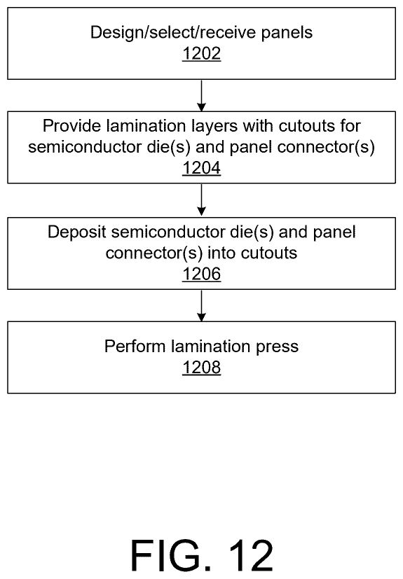

FIG. 12 is a flowchart illustrating example operations for forming modular embedded semiconductor device packages of FIGS. 1-11. In the example of FIG. 12, pre-formed panels may be designed, selected, and/or received (1202). For example, the panels 402, 404 of FIG. 4 may be designed by a semiconductor manufacturer and built by a packaging provider (e.g., PCB provider). Panels with existing designs may simply be selected and purchased by a semiconductor manufacturer. As described above, panels may be designed and implemented with patterned layers of sinter paste.

Lamination layers with cutouts may be provided (1204). For example, the lamination layer 401 of FIGS. 4 and 5 may be provided with cutouts for at least one semiconductor device/chip scale package and for at least one panel connector, as shown in those figures.

Thus, the semiconductor die(s) and panel connector(s) may be deposited into the cutouts (1206). Then, a lamination press may be performed to apply heat and pressure to the assembled package. This process provides encapsulation of the semiconductor die(s) and panel connector(s) using the lamination layer(s), and simultaneously provides sintering of the previously provided and positioned sinter paste.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a DBM substrate can be formed by bonding one or more metal layers (e.g., a first metal layer, second metal layer) to an insulating layer. In some implementations, one or more of the metal layers can be bonded to the insulating layer using, for example, a high-temperature process.

In some implementations, a DBM substrate can include an insulating layer disposed between the first metal layer and the second metal layer. The insulating layer can be, for example, a ceramic layer. In some implementations, the insulating layer can be or can include, for example, a ceramic material such as alumina (Al₂O₃) or aluminum nitride (AlN).

In some implementations, one or more metal layers can be or can function as a heat sink. In some implementations, the one or more metal layers can be coupled to a heat sink. In some implementations, at least a portion of the one or more metal layers can be exposed through a molding material.

In some implementations, the one or more metal layers can be or can include a patterned metal layer including one or more electrically conductive traces. In some implementations, the one or more metal layers can be or can include a patterned layer configured to form one or more electrical circuits, one or more conductive blind and/or through vias, and/or so forth.

In some implementations, the DBM substrate can be, or can include, a direct bonded copper (DBC) substrate. In some implementations, such as in DBC substrate implementations, the metal layers of the DBC may be, or may include, a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor dies may be also connected to lead frame posts by electrical connections such as wirebonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

In some implementations, a mold material (e.g., molding material or compound, an encapsulation material) can be or can include a non-conducting layer/material.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer)

In some implementations, a module (e.g., a package including a semiconductor device) can be included in another module. The module can be referred to as a package. For example, one or more modules can be one or more sub modules included within another module. In other words, a first module can be included as a sub module within a second module.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor device package, comprising:
a first panel including at least one first connection;
a second panel including at least one second connection;
a semiconductor device, with a first surface of the semiconductor device attached to the first panel and connected to the at least one first connection, and with a second surface of the semiconductor device, opposed to the first surface of the semiconductor device, attached to the second panel and connected to the at least one second connection; and
a panel connector, with a first surface of the panel connector attached to the first panel, and with a second surface of the panel connector, opposed to the first surface of the panel connector, attached to the second panel, the panel connector thereby coupling the first panel to the second panel.

2. The semiconductor device package of claim 1, wherein the first surface of the panel connector is electrically connected to the at least one first connection and the second surface of the panel connector is electrically connected to the at least one second connection.

3. The semiconductor device package of claim 1, wherein the first panel is sinter attached to the first surface of the semiconductor device, and the second panel is sinter attached to the second surface of the semiconductor device.

4. The semiconductor device package of claim 1, wherein the first panel is sinter attached to the first surface of the panel connector, and the second panel is sinter attached to the second surface of the panel connector.

5. The semiconductor device package of claim 1, further comprising:
an encapsulant disposed between the first panel and the second panel, and around the semiconductor device and the panel connector.

6. The semiconductor device package of claim 1, wherein the first panel includes a first printed circuit board (PCB) and the second panel includes a second PCB.

7. The semiconductor device package of claim 1, wherein the at least one first connection includes microvias with metal interconnects formed therein and providing at least one external connection to the semiconductor device by way of the first panel.

8. The semiconductor device package of claim 1, wherein the at least one second connection includes metal interconnects between the second surface of the semiconductor device and the second surface of the panel connector.

9. The semiconductor device package of claim 1, wherein the at least one second connection includes a leadframe.

10. The semiconductor device package of claim 1, wherein the second panel includes a ceramic isolation layer adjacent to the at least one second connection.

11. A package for an embedded semiconductor device, the package comprising:
a first panel;
a second panel;
a semiconductor device, with a first surface of the semiconductor device attached to the first panel, and with a second surface of the semiconductor device, opposed to the first surface of the semiconductor device, attached to the second panel;
a panel connector, with a first surface of the panel connector attached to the first panel, and with a second surface of the panel connector, opposed to the first surface of the panel connector, attached to the second panel, the panel connector thereby bonding the first panel to the second panel; and
an encapsulant disposed between the first panel and the second panel, and around the semiconductor device and the panel connector.

12. The package of claim 11, wherein a first surface of the panel connector is electrically connected to at least one first connection of the first panel and the second surface of the panel connector is electrically connected to at least one second connection of the second panel.

13. The package of claim 12, wherein:
the at least one first connection includes microvias with metal interconnects formed therein and providing at least one external connection to the semiconductor device by way of the first panel; and
the at least one second connection includes metal interconnects between the second surface of the semiconductor device and the second surface of the panel connector.

14. The package of claim 12, wherein the second panel includes a ceramic isolation layer adjacent to the at least one second connection.

15. The package of claim 11, wherein the first panel is sinter attached to the first surface of the semiconductor device, the second panel is sinter attached to the second surface of the semiconductor device, the first panel is sinter attached to the first surface of the panel connector, and the second panel is sinter attached to the second surface of the panel connector.

16. The package of claim 11, wherein the first panel includes a first printed circuit board (PCB) and the second panel includes a second PCB.

17. A method of forming a semiconductor device package, comprising:
forming a cutout layer with at least a first cutout and a second cutout;
disposing a semiconductor device in the first cutout and a panel connector in the second cutout;
disposing the cutout layer, the semiconductor device and the panel connector between a first panel and a second panel; and
performing a coupling process to couple the semiconductor device and the panel connector to the first panel and the second panel, and to form an encapsulant around the semiconductor device and the panel connector between the first panel and the second panel.

18. The method of claim 17, further comprising:
bonding a first surface of the semiconductor device to the first panel;
bonding a second surface of the semiconductor device, opposed to the first surface of the semiconductor device, to the second panel;
bonding a first surface of the panel connector to the first panel; and
bonding a second surface of the panel connector, opposed to the first surface of the panel connector, to the second panel.

19. The method of claim 18, further comprising:
aligning first sinter paste formed on the first panel with the first surface of the semiconductor device and the first surface of the panel connector; and
aligning second sinter paste formed on the second panel with the second surface of the semiconductor device and the second surface of the panel connector.

20. The method of claim 19, wherein performing the coupling process further comprises:
performing a lamination press that sinters the semiconductor device to the first panel and the second panel, and that sinters the panel connector to the first panel and the second panel, using the first sinter paste and the second sinter paste.
